(19) United States
(12) Patent Application Publication
(10) Pub. No.: US 2025/0273531 A1
(43) Pub. Date: Aug. 28, 2025

(54) PACKAGE STRUCTURE

(71) Applicant: Advanced Semiconductor Engineering, Inc., Kaohsiung (TW)

(72) Inventors: Hong-Te LIEN, Kaohsiung (TW); Yi-Chieh CHEN, Kaohsiung (TW); Wen Hung HUANG, Kaohsiung (TW); Yu-Hsun CHANG, Kaohsiung (TW)

(73) Assignee: Advanced Semiconductor Engineering, Inc., Kaohsiung (TW)

(21) Appl. No.: 18/586,405

(22) Filed: Feb. 23, 2024

(51) Int. Cl. H01L 23/367; H01L 23/00; H01L 23/498; H01L 25/065

(52) U.S. Cl. CPC H01L 23/3675; H01L 23/49816; H01L 23/49822; H01L 24/08; H01L 24/16; H01L 25/0652; H01L 2224/08146; H01L 2224/08155; H01L 2224/16146; H01L 2224/16148; H01L 2924/1431; H01L 2924/1434; H01L 2924/15311; H01L 2924/182

(57) ABSTRACT

An electronic structure includes a package structure, a first heat dissipating structure and a second heat dissipating structure. The package structure has a top surface including a first region and a second region. A first predetermined temperature at the first region is higher than a second predetermined temperature at the second region. The first heat dissipating structure includes a first portion disposed on the first region. The second heat dissipating structure includes a first portion disposed on the second region. The first portion of the first heat dissipating structure and the first portion of the second heat dissipating structure are concurrently formed through a 3D printing technique. A thickness of the first portion of the first heat dissipating structure is greater than a thickness of the first portion of the second heat dissipating structure.

### BACKGROUND

### 1. Field of the Disclosure

The present disclosure relates to a package structure and a manufacturing method, and to a package structure including a heat dissipating structure, and a method for manufacturing the same.

### 2. Description of the Related Art

In a semiconductor electronic structure, a semiconductor package structure is mounted to a substrate, and a heat dissipating structure is formed or disposed on a top surface of the semiconductor package structure so as to dissipate the heat generated from the semiconductor device(s) in the semiconductor package structure during operation to a heat sink disposed over the heat dissipating structure. The design of the heat dissipating structure will influence the heat dissipation efficiency of the semiconductor electronic structure, and will affect the reliability, yield and lifetime of the semiconductor electronic structure.

### SUMMARY

In some embodiments, an electronic structure includes a package structure, a first heat dissipating structure and a second heat dissipating structure. The package structure has a top surface including a first region and a second region. A first predetermined temperature at the first region is higher than a second predetermined temperature at the second region. The first heat dissipating structure includes a first portion disposed on the first region. The second heat dissipating structure includes a first portion disposed on the second region. The first portion of the first heat dissipating structure and the first portion of the second heat dissipating structure are concurrently formed through a 3D printing technique. A thickness of the first portion of the first heat dissipating structure is greater than a thickness of the first portion of the second heat dissipating structure.

In some embodiments, an electronic structure includes a package structure, a heat sink, a first heat dissipating structure and a second heat dissipating structure. The package structure includes a first electronic device and a second electronic device encapsulated by an encapsulant. The heat sink is disposed over the package structure. The first heat dissipating structure is disposed over the first electronic device, and has a first thermal path toward heat sink. The second heat dissipating structure is disposed over the second electronic device, and has a second thermal path toward heat sink. The first thermal path is thermally insulated from the second thermal path. The first thermal path is non-parallel with the second thermal path.

In some embodiments, an electronic structure includes a package structure. The package structure includes an electronic device, an encapsulant and a vertical conductive structure. The encapsulant encapsulates the electronic device. The vertical conductive structure is encapsulated in the encapsulant and has a discontinuous lateral surface.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an electronic structure according to some embodiments of the present disclosure.

FIG. 2 illustrates a cross-sectional view of an electronic structure according to some embodiments of the present disclosure.

FIG. 3 illustrates a cross-sectional view of an electronic structure according to some embodiments of the present disclosure.

FIG. 4 illustrates a cross-sectional view of an electronic structure according to some embodiments of the present disclosure.

FIG. 5 illustrates a cross-sectional view of an electronic structure according to some embodiments of the present disclosure.

FIG. 6 illustrates a cross-sectional view of an electronic structure according to some embodiments of the present disclosure.

FIG. 7 illustrates a perspective view of the electronic structure of FIG. 6.

FIG. 7A illustrates a top view of FIG. 7.

FIG. 8 illustrates a cross-sectional view of an electronic structure according to some embodiments of the present disclosure.

FIG. 8A illustrates an enlarged view of a region “A” in FIG. 8.

FIG. 9 illustrates a cross-sectional view of an electronic structure according to some embodiments of the present disclosure.

FIG. 9A illustrates an enlarged view of a region “B” in FIG. 9.

FIG. 9B illustrates a cross-sectional view of an electronic structure according to some embodiments of the present disclosure.

FIG. 10 illustrates a cross-sectional view of an electronic structure according to some embodiments of the present disclosure.

FIG. 11 illustrates a cross-sectional view of an electronic structure according to some embodiments of the present disclosure.

FIG. 12 illustrates a cross-sectional view of an electronic structure according to some embodiments of the present disclosure.

FIG. 13 illustrates a cross-sectional view of an electronic structure according to some embodiments of the present disclosure.

FIG. 14 illustrates a cross-sectional view of an electronic structure according to some embodiments of the present disclosure.

FIG. 15 illustrates a cross-sectional view of an electronic structure according to some embodiments of the present disclosure.

FIG. 16 illustrates a cross-sectional view of an electronic structure according to some embodiments of the present disclosure.

FIG. 17 illustrates one or more stages of an example of a method for manufacturing an electronic structure according to some embodiments of the present disclosure.

FIG. 18 illustrates one or more stages of an example of a method for manufacturing an electronic structure according to some embodiments of the present disclosure.

FIG. 19 illustrates one or more stages of an example of a method for manufacturing an electronic structure according to some embodiments of the present disclosure.

FIG. 20 illustrates one or more stages of an example of a method for manufacturing an electronic structure according to some embodiments of the present disclosure.

FIG. 21 illustrates one or more stages of an example of a method for manufacturing an electronic structure according to some embodiments of the present disclosure.

FIG. 22 illustrates one or more stages of an example of a method for manufacturing an electronic structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

At least some embodiments of the present disclosure provide for a package structure which has an improved crack resistance. In some embodiments, an electronic structure includes such package structure so as to improve a reliability or a yield thereof. At least some embodiments of the present disclosure further provide for techniques for manufacturing the package structure and the electronic structure.

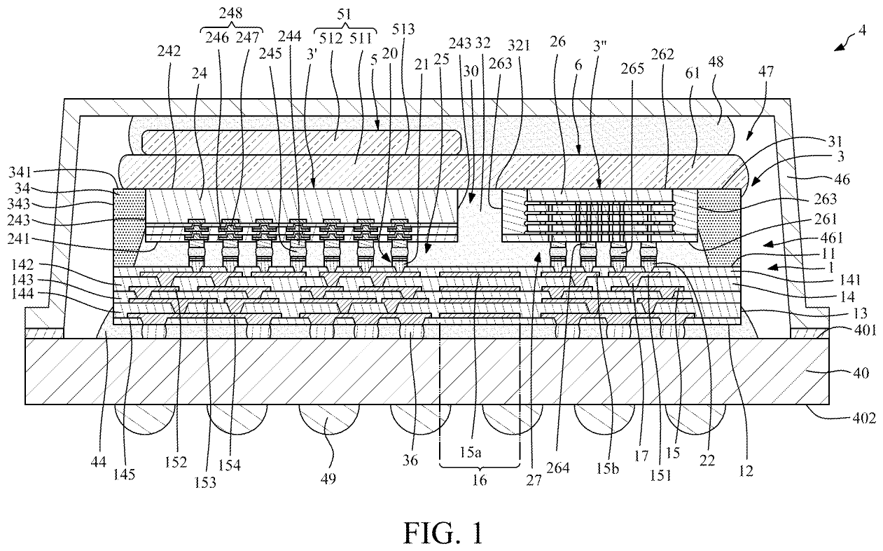

FIG. 1 illustrates a cross-sectional view of an electronic structure 4 according to some embodiments of the present disclosure. The electronic structure 4 may be also referred to as “an assembly structure” or “a semiconductor package”. The electronic structure 4 may include a base substrate 40, a package structure 3, a second protection material 44, a thermal structure 47 (including a first heat dissipating structure 5 and a second heat dissipating structure 6), a thermal material 48, a heat sink 46 and a plurality of external connectors 49.

The base substrate 40 may include a glass reinforced epoxy material (such as FR4), bismaleimide triazine (BT), epoxy resin, silicon, printed circuit board (PCB) material, glass, ceramic or photoimageable dielectric (PID) material. The base substrate 40 may have a first surface 401 and a second surface 402 opposite to the first surface 401.

The package structure 3 may include a wiring structure 1, a first electronic device 24, a second electronic device 26, a first protection material 32, an encapsulant 34 and a plurality of solder materials 36. In some embodiments, the package structure 3 may include one first electronic device 24 and two second electronic devices 26 disposed side by side. However, the amounts of the first electronic device(s) 24 and the second electronic device(s) 26 are not limited in the present disclosure.

The wiring structure 1 may have a first surface 11, a second surface 12 opposite to the first surface 11, a lateral side surface 13 extending between the first surface 11 and the second surface 12, and a high density region 16 (or a fine line region) between the first electronic device 24 and the second electronic device 26. The wiring structure 1 may include at least one dielectric layer 14, at least one circuit layer 15 in contact with the dielectric layer 14, and a plurality of protrusion pads 20. For example, the wiring structure 1 includes a first dielectric layer 141, a first circuit layer 151, a second dielectric layer 142, a second circuit layer 152, a third dielectric layer 143, a third circuit layer 153, a fourth dielectric layer 144, a fourth circuit layer 154, and a fifth dielectric layer 145.

The first dielectric layer 141 may be a topmost dielectric layer or an outermost dielectric layer of the wiring structure 1. The first circuit layer 151 may be a topmost circuit layer or an outermost circuit layer of the wiring structure 1. A material of the first circuit layer 151 may include, for example, copper, another conductive metal, or an alloy thereof. A material of the first dielectric layer 141 may include an insulating material, a passivation material, a dielectric material or a solder resist material, such as, for example, a benzocyclobutene (BCB) based polymer or a polyimide (PI). In some embodiments, the first dielectric layer 141 may be made of a photoimageable material. In addition, the first surface 11 of the wiring structure 1 may be a top surface of the first dielectric layer 141. The first circuit layer 151 is disposed adjacent to the top surface of the first dielectric layer 141. In some embodiments, the first circuit layer 151 is embedded in the first dielectric layer 141, and is exposed from the top surface of the first dielectric layer 141. That is, the first dielectric layer 141 covers the first circuit layer 151, and defines a plurality of openings to expose portions of the first circuit layer 151.

Further, the first circuit layer 151 may include an interconnection portion 15a and a periphery portion 15b. The interconnection portion 15a is located in the high density region 16, and the periphery portion 15b is located outside the high density region 16 (e.g., a low density region). For example, the second electronic device 26 may be electrically connected to the first electronic device 24 through the interconnection portion 15a of the first circuit layer 151. The second electronic device 26 and the first electronic device 24 may be electrically connected to the solder materials 36 on the second surface 12 of the wiring structure 1 through the periphery portion 15b of the first circuit layer 151. A line width/line space (L/S) of the traces of the interconnection portion 15a may be less than an L/S of the traces of the periphery portion 15b. For example, an L/S of the traces of the interconnection portion 15a may be less than or equal to about 5 μm/about 5 μm, or less than or equal to about 2 μm/about 2 μm, or less than or equal to about 0.8 μm/about 0.8 μm. An L/S of the traces of the periphery portion 15b may be less than or equal to about 10 μm/about 10 μm, or less than or equal to about 7 μm/about 7 μm, or less than or equal to about 5 μm/about 5 μm.

The first dielectric layer 141 and the first circuit layer 151 may be disposed on the second dielectric layer 142. In addition, the second dielectric layer 142 may cover the second circuit layer 152. A portion (i.e., a via portion 17) of the first circuit layer 151 extends through the second dielectric layer 142 to electrically connect the second circuit layer 152. A material of the second dielectric layer 142 may be the same as or similar to the material of the first dielectric layer 141. The second circuit layer 152 may also include an interconnection portion located in the high density region 16, and a periphery portion located outside the high density region 16. In some embodiments, the via portion 17 of the first circuit layer 151 may extend from the periphery portion 15b, and they may be formed concurrently and integrally.

Similarly, the second dielectric layer 142 and the second circuit layer 152 may be disposed on the third dielectric layer 143. In addition, the third dielectric layer 143 may cover the third circuit layer 153. A portion (i.e., a via portion 17) of the second circuit layer 152 extends through the third dielectric layer 143 to electrically connect the third circuit layer 153. A material of the third dielectric layer 143 may be the same as or similar to the material of the second dielectric layer 142. The third circuit layer 153 may also include an interconnection portion located in the high density region 16, and a periphery portion located outside the high density region 16. In some embodiments, the via portion 17 of the second circuit layer 152 may extend from the periphery portion, and they may be formed concurrently and integrally.

Similarly, the third dielectric layer 143 and the third circuit layer 153 may be disposed on the fourth dielectric layer 144. In addition, the fourth dielectric layer 144 may cover the fourth circuit layer 154. A portion (i.e., a via portion 17) of the third circuit layer 153 extends through the fourth dielectric layer 144 to electrically connect the fourth circuit layer 154. A material of the fourth dielectric layer 144 may be the same as or similar to the material of the third dielectric layer 143. The fourth circuit layer 154 may also include an interconnection portion located in the high density region 16, and a periphery portion located outside the high density region 16.

The fourth dielectric layer 144 and the fourth circuit layer 154 may be disposed on the fifth dielectric layer 145. A portion (i.e., a via portion 17) of the fourth circuit layer 154 extends through the fifth dielectric layer 145 to be exposed from a bottom surface of the fifth dielectric layer 145 (e.g., the second surface 12 of the wiring structure 1). A material of the fifth dielectric layer 145 may be the same as or similar to the material of the fourth dielectric layer 144. As shown in FIG. 1, the second electronic device 26 may be electrically connected to the first electronic device 24 through the interconnection portions 15a of the circuit layers 15 (including, for example, the interconnection portions 15a of the first circuit layer 151, the second circuit layer 152, the third circuit layer 153 and the fourth circuit layer 154). The second electronic device 26 and the first electronic device 24 may be electrically connected to the solder materials 36 through the via portions 17 of the periphery portions 15b of the circuit layers 15 (including, for example, the periphery portions 15b of the first circuit layer 151, the second circuit layer 152, the third circuit layer 153 and the fourth circuit layer 154).

The protrusion pads 20 may be disposed on and protrude from the first dielectric layer 141 (i.e., the topmost dielectric layer or the outermost dielectric layer) of the wiring structure 1. The protrusion pads 20 may be disposed on and protrude from the first surface 11 of the wiring structure 1, and extend through the first dielectric layer 141 (i.e., the topmost dielectric layer or the outermost dielectric layer) to electrically connect the first circuit layer 151. The protrusion pads 20 may include a plurality of first protrusion pads 21 corresponding to the first electronic device 24 and a plurality of second protrusion pads 22 corresponding to the second electronic device 26.

The first electronic device 24 and the second electronic device 26 are disposed adjacent to the first surface 11 of the wiring structure 1 side by side, and are electrically connected to the circuit layer 15 of the wiring structure 1. The first electronic device 24 may be a semiconductor device such as an application specific integrated circuit (ASIC) die. The first electronic device 24 may have a first surface 241, a second surface 242 opposite to the first surface 241, and a lateral side surface 243 extending between the first surface 241 and the second surface 242. Further, the first electronic device 24 may include a plurality of circuit layers 248 and a plurality of first electrical contacts 244 disposed adjacent to the first surface 241. The circuit layer 248 may be embedded in the first electronic device 24, and may include a seed layer 246 and a conductive material 247 disposed on the seed layer 246. The seed layer 246 may be formed by physical vapor deposition (PVD). The first electrical contacts 244 may be electrically connected to the circuit layers 248, and may be exposed or may protrude from the first surface 241 for electrical connection. The first electrical contacts 244 may be pads, bumps, studs, pillars or posts. In some embodiments, the first electrical contacts 244 of the first electronic device 24 may be electrically connected and physically connected to the first protrusion pads 21 through a plurality of solder materials 245. In other words, the first electronic device 24 may be electrically connected to the wiring structure 1 by flip-chip bonding. For example, the first electrical contacts 244 may include copper, gold, platinum, and/or other suitable material. The first electronic device 24 will generate relatively more heat during operation.

The second electronic device 26 may be a semiconductor device such as a high bandwidth memory (HBM) die or an ASIC die. The second electronic device 26 may have a first surface 261, a second surface 262 opposite to the first surface 261, and a lateral side surface 263 extending between the first surface 261 and the second surface 262. Further, the second electronic device 26 may include a plurality of second electrical contacts 264 disposed adjacent to the first surface 261. The second electrical contacts 264 may be exposed or may protrude from the first surface 261 for electrical connection. The second electrical contacts 264 may be pads, bumps, studs, pillars or posts. In some embodiments, the second electrical contacts 264 of the second electronic device 26 may be electrically connected and physically connected to the second protrusion pads 22 through a plurality of solder materials 265. In other words, the second electronic device 26 may be electrically connected to the wiring structure 1 by flip-chip bonding. For example, the second electrical contact 264 may include copper, gold, platinum, and/or other suitable material. The second electronic device 26 will generate relatively less heat during operation. The amount of heat generated by the second electronic device 26 may be less than the amount of heat generated by the first electronic device 24.

The first protection material 32 (i.e., an underfill) is disposed in the first space 25 between the first electronic device 24 and the wiring structure 1 and the second space 27 between the second electronic device 26 and the wiring structure 1 so as to cover and protect the joints formed by the first electrical contacts 244, the first protrusion pads 21 and the solder materials 245, and the joints formed by the second electrical contacts 264, the second protrusion pads 22 and the solder materials 265. In some embodiments, the first protection material 32 may extend from the first space 25 to the second space 27. In addition, the first protection material 32 may further extend into a gap 30 between the lateral side surface 243 of the first electronic device 24 and the lateral side surface 263 of the second electronic device 26. The gap 30 may be less than about 100 μm, less than about 80 μm, less than about 70 μm, less than about 60 μm, or less than about 50 μm. Thus, the first protection material 32 may fill the gap 30 due to capillarity. The first protection material 32 has a top surface 321.

The encapsulant 34 may encapsulate the wiring structure 1, the first electronic device 24, the second electronic device 26 and the first protection material 32. Alternatively, the encapsulant 34 may cover at least a portion of the first surface 11 of the wiring structure 1, at least a portion of the first electronic device 24, at least a portion of the second electronic device 26 and the first protection material 32. A material of the encapsulant 34 may be a molding compound with or without fillers. The encapsulant 34 has a first surface 341 (e.g., a top surface) and a lateral side surface 343. The first surface 341 of the encapsulant 34, the second surface 242 of the first electronic device 24, the second surface 262 of the second electronic device 26 and the top surface 321 of the first protection material 32 in the gap 30 may be substantially aligned with or coplanar with each other so as to form a top surface 31 of the package structure 3. In addition, the lateral side surface 343 of the encapsulant 34 may be substantially aligned with or coplanar with the lateral side surface 13 of the wiring structure 1.

The solder materials 36 (e.g., solder balls) are disposed adjacent to the second surface 12 of the wiring structure 1 for external connection. The solder materials 36 are disposed on the exposed portions (i.e., the bottom portions of the via portions) of the fourth circuit layer 154. The package structure 3 may be electrically connected to the first surface 401 of the base substrate 40 through the solder materials 36. The second protection material 44 (i.e., an underfill) may be disposed in a space between the package structure 3 and the base substrate 40 so as to cover and protect the solder materials 36.

In some embodiments, the package structure 3 may include a first region 3′ and a second region 3″ different from the first region 3′. For example, the top surface 31 of the package structure 3 may include the first region 3′ and the second region 3″. The first electronic device 24 may be disposed corresponding to or disposed in the first region 3′, and may generate heat causing a first predetermined temperature. Form a top view, the first electronic device 24 may be disposed within the first region 3′. The second electronic device 26 may be disposed corresponding to or disposed in the second region 3″, and may be configured to generate heat causing a second predetermined temperature. Form a top view, the second electronic device 26 may be disposed within the second region 3″.

The first predetermined temperature at the first region 3′ is higher than a second predetermined temperature at the second region 3″ during the operation of the package structure 3. Thus, the first region 3′ may be also referred to as “a hot region”, “a high temperature region”, “a hot area”, “a high temperature area”, “a first portion”, “a high temperature portion” or “a hot portion”. The first electronic device 24 may include the first region 3′. Since the encapsulant 34 and/or the first protection material 32 may encapsulate the first electronic device 24, the range or area of the first region 3′ may include a portion of the encapsulant 34 and/or the first protection material 32 that surrounds the first electronic device 24. That is, a width of the first region 3′ may be greater than a width of the first electronic device 24 from a cross-sectional view and a top view.

The second region 3″ may be also referred to as “a cold region”, “a low temperature region”, “a cold area”, “a low temperature area”, “a second portion”, “a low temperature portion” or “a cold portion”. The second electronic device 26 may include the second region 3″. Since the encapsulant 34 and/or the first protection material 32 may encapsulate the second electronic device 26, the range or area of the second region 3″ may include a portion of the encapsulant 34 and/or the first protection material 32 that surrounds the second electronic device 26. That is, a width of the second region 3″ may be greater than a width of the second electronic device 26 from a cross-sectional view and a top view.

The thermal structure 47 may include a first heat dissipating structure 5 and a second heat dissipating structure 6, and may be disposed on the top surface 31 of the package structure 3 (e.g., the first surface 341 of the encapsulant 34, the second surface 242 of the first electronic device 24, the second surface 262 of the second electronic device 26 and the top surface 321 of the first protection material 32). The first heat dissipating structure 5 and the second heat dissipating structure 6 may be formed through a chemical deposition process such as a 3D printing technique. A material of the first heat dissipating structure 5 and the second heat dissipating structure 6 may be metal such as copper. A grain size of the material of the first heat dissipating structure 5 and the second heat dissipating structure 6 may be greater than a grain size of the material of the seed layer 246 of the circuit layer 248 of the first electronic device 24. For example, the grain size of the material of the first heat dissipating structure 5 and the second heat dissipating structure 6 may be greater than five times, ten times, or twenty times the grain size of the material of the seed layer 246 of the circuit layer 248 of the first electronic device 24.

The first heat dissipating structure 5 may be disposed over or disposed on the first region 3′ of the first electronic device 24. The first heat dissipating structure 5 may include a first portion 51 disposed on the first region 3′. The first portion 51 of the first heat dissipating structure 5 may directly contact the first surface 341 of the encapsulant 34, the second surface 242 of the first electronic device 24 and the top surface 321 of the first protection material 32. The first portion 51 of the first heat dissipating structure 5 may include a lower portion 511 and an upper portion 512 disposed on the lower portion 511. A thickness of the upper portion 512 may be less than a thickness of the lower portion 511. There may be a visible interface or an obvious interface (e.g., the top surface 513 of the lower portion 511) formed between the lower portion 511 and the upper portion 512. In another embodiment, there may be no obvious interface or visible interface formed between the lower portion 511 and the upper portion 512. In addition, the upper portion 512 of the first portion 51 of the first heat dissipating structure 5 may include a rounded corner.

The second heat dissipating structure 6 may be disposed over or disposed on the second region 3″ of the second electronic device 26. The second heat dissipating structure 6 may include a first portion 61 disposed on the second region 3″. The first portion 61 of the second heat dissipating structure 6 may directly contact the first surface 341 of the encapsulant 34, the second surface 262 of the second electronic device 26 and the top surface 321 of the first protection material 32. A portion of the first portion 61 of the second heat dissipating structure 6 may extend to contact the lateral side surface 343 of the encapsulant 34.

In the illustrated embodiment, a size (e.g., thickness) of the heat dissipating structure may be determined according to the amount of heat generated by the electronic device. For example, the amount of heat generated by the first electronic device 24 may be greater than the amount of heat generated by the second electronic device 26, thus, the size (e.g., a thickness from a cross-sectional view or a coverage area form a top view) of the first heat dissipating structure 5 on the first region 3′ may be greater than the size (e.g., a thickness from a cross-sectional view or a coverage area form a top view) of the second heat dissipating structure 6 on the second region 3″.

The first portion 51 of the first heat dissipating structure 5 and the first portion 61 of the second heat dissipating structure 6 may be concurrently formed through a chemical deposition process. A thickness of the first portion 51 of the first heat dissipating structure 5 is greater than a thickness of the first portion 61 of the second heat dissipating structure 6. In some embodiments, the lower portion 511 of the first portion 51 of the first heat dissipating structure 5 and the first portion 61 of the second heat dissipating structure 6 may be concurrently formed through a chemical deposition process. A thickness of the lower portion 511 of the first portion 51 of the first heat dissipating structure 5 is equal to the thickness of the first portion 61 of the second heat dissipating structure 6.

The thermal material 48 (e.g., a thermal interface material (TIM)) may cover the first heat dissipating structure 5 and the second heat dissipating structure 6. The heat sink 46 may be a cap or hat structure, and may define a cavity 461 for accommodating the package structure 3. A material of the heat sink 46 may include metal such as copper, aluminum, and/or other suitable material. The heat sink 46 may be disposed over the package structure 3. A portion of the heat sink 46 may be attached to the top surface 31 of the package structure 3 through the thermal material 48 (e.g., thermal interface material (TIM)) so as to dissipate the heat generated by the first electronic device 24 and the second electronic device 26. Thus, the heat sink 46 may contact the thermal material 48 (e.g., thermal interface material (TIM)). The heat sink 46 may not directly contact the first heat dissipating structure 5 and the second heat dissipating structure 6. The heat sink 46 is spaced apart from the first heat dissipating structure 5 and the second heat dissipating structure 6. The heat sink 46 may be thermally connected with the first heat dissipating structure 5 and the second heat dissipating structure 6 through the thermal material 48. Another portion (e.g., bottom portion) of the heat sink 46 may be attached to or thermally connected to the base substrate 40 through an adhesive material. In addition, the external connectors 49 (e.g., solder balls) are formed or disposed on the second surface 402 of the base substrate 40 for external connection.

In the embodiment illustrated in FIG. 1, a first thermal path may be formed from the first region 3′ (e.g., the first electronic device 24) to the heat sink 46 by the first heat dissipating structure 5 and a first portion of the thermal material 48 on the first heat dissipating structure 5. A second thermal path may be formed from the second region 3″ (e.g., the second electronic device 26) to the heat sink 46 by the second heat dissipating structure 6 and a second portion of the thermal material 48 on the second heat dissipating structure 6. During the operation of the package structure 3, the temperature of the first region 3′ (e.g., the first electronic device 24) may be higher than the temperature of the second region 3″ (e.g., the second electronic device 26). However, since the thickness of the first heat dissipating structure 5 is greater than the thickness of the second heat dissipating structure 6, a heat dissipation efficiency (or thermal conductivity) of the first thermal path is greater than a heat dissipation efficiency (or thermal conductivity) of the second thermal path. Thus, the heat of the first region 3′ (e.g., the heat generated by the first electronic device 24) and the heat of the second region 3″ (e.g., the heat generated by the second electronic device 26) may be dissipated or conducted to the heat sink 46 substantially evenly. Therefore, the heat of the first region 3′ (e.g., the heat generated by the first electronic device 24) will not accumulate at the first region 3′, and the performance of the package structure 3 may be improved. Therefore, the reliability, yield and lifetime of the electronic structure 4 is improved.

In addition, the first heat dissipating structure 5 and the second heat dissipating structure 6 are formed through a chemical deposition process (e.g., 3D printing technology) rather than a physical vapor deposition (PVD). Thus, the manufacturing cost of the first heat dissipating structure 5 and the second heat dissipating structure 6 may be reduced, and the manufacturing cost of the electronic structure 4 may be also reduced. Further, since the first heat dissipating structure 5 and the second heat dissipating structure 6 are formed through the chemical deposition process (e.g., 3D printing technique or 3D printing technology), the pattern, profile and shape of the first heat dissipating structure 5 and the second heat dissipating structure 6 may be formed flexibly. That is, the first thermal path and the second thermal path may be designed as desired. By adjusting the direction of length of the first thermal path and the second thermal path, the heat dissipation efficiency of the package structure 3 may be optimized. Compared to the metal formed by physical vapor deposition (PVD), an advantage of the 3D printing technique is that different geometries and sizes of the heat dissipating structure may be selected or chosen to be formed on different regions. Thus, the design flexibility is improved.

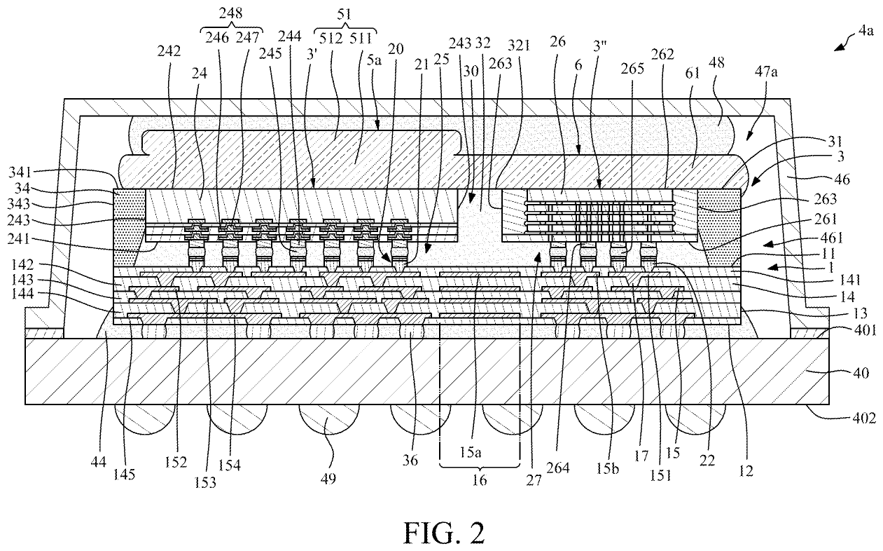

FIG. 2 illustrates a cross-sectional view of an electronic structure 4a according to some embodiments of the present disclosure. The electronic structure 4a of FIG. 2 is similar to the electronic structure 4 of FIG. 1, except for the structure of the first heat dissipating structure 5a of the thermal structure 47a. As shown in FIG. 2, there may be no obvious interface or visible interface between the lower portion 511 and the upper portion 512.

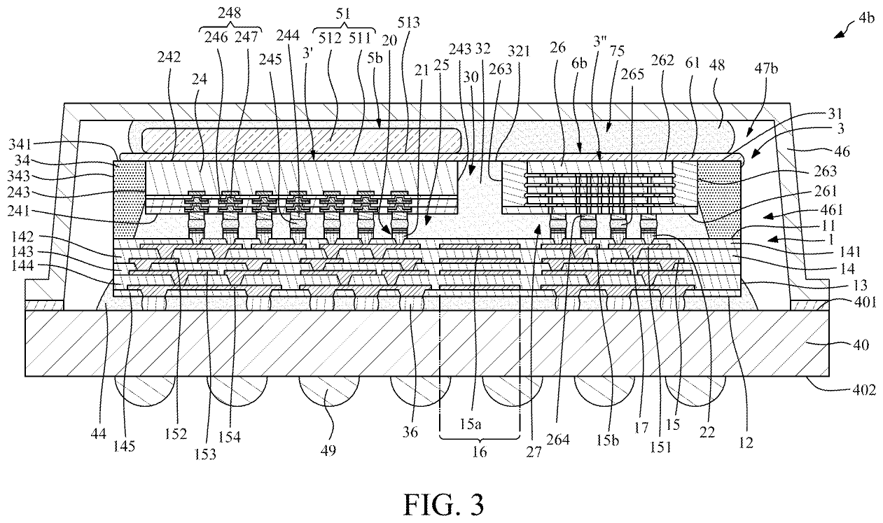

FIG. 3 illustrates a cross-sectional view of an electronic structure 4b according to some embodiments of the present disclosure. The electronic structure 4b of FIG. 3 is similar to the electronic structure 4 of FIG. 1, except for the structure of the thermal structure 47b. As shown in FIG. 3, the thickness of the first portion 51 of the first heat dissipating structure 5b is greater than a thickness of the first portion 61 of the second heat dissipating structure 6b. The thickness of the upper portion 512 may be greater than the thickness of the lower portion 511. The thickness of the lower portion 511 of the first portion 51 of the first heat dissipating structure 5b is equal to the thickness of the first portion 61 of the second heat dissipating structure 6b.

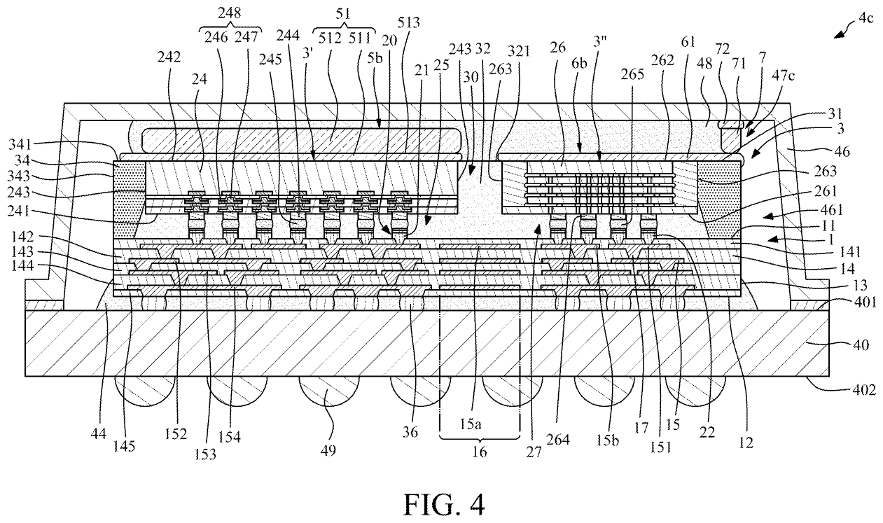

FIG. 4 illustrates a cross-sectional view of an electronic structure 4c according to some embodiments of the present disclosure. The electronic structure 4c of FIG. 4 is similar to the electronic structure 4b of FIG. 3, and the differences therebetween are described as follows. The first heat dissipating structure 5b may be physically separated from and or thermally insulated form the second heat dissipating structure 6b. The thermal material 48 (e.g., thermal interface material (TIM)) may extend between the first heat dissipating structure 5b and the second heat dissipating structure 6b, and may connect to the heat sink 46. For example, the lower portion 511 of the first portion 51 of the first heat dissipating structure 5b may be spaced apart from the first portion 61 of the second heat dissipating structure 6b. In addition, the thermal structure 47c may further include a third heat dissipating structure 7 connecting to a periphery portion of the first portion 61 of the second heat dissipating structure 6b. A thickness of the third heat dissipating structure 7 may be greater than the thickness of the upper portion 512 of the first portion 51 of the first heat dissipating structure 5b. Thus, a level of a top end of the third heat dissipating structure 7 may be higher than a top end of the first heat dissipating structure 5b and a top end of the second heat dissipating structure 6b. An elevation of a top surface of the third heat dissipating structure 7 may be higher than an elevation of a top surface of the first heat dissipating structure 5b and an elevation of a top surface of the second heat dissipating structure 6b. In some embodiments, the third heat dissipating structure 7 may include a first portion 71 disposed on the first portion 61 of the second heat dissipating structure 6b and a second portion 72 disposed on the first portion 71. A width of the first portion 71 may be less than a width of the second portion 72. In some embodiments, the third heat dissipating structure 7 may be formed through the chemical deposition process (e.g., 3D printing technique or 3D printing technology). The heat sink 46 may contact the third heat dissipating structure 7.

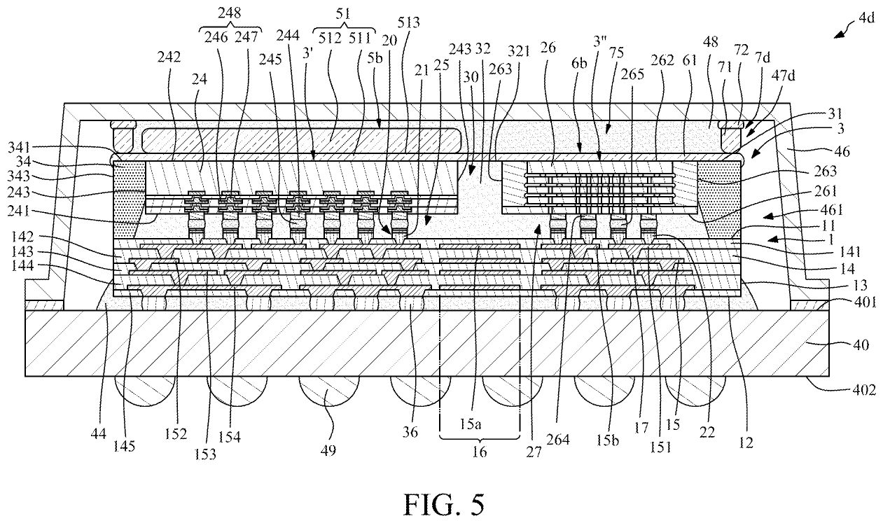

FIG. 5 illustrates a cross-sectional view of an electronic structure 4d according to some embodiments of the present disclosure. The electronic structure 4d of FIG. 5 is similar to the electronic structure 4b of FIG. 3, except that the thermal structure 47d may further include a third heat dissipating structure 7d. The third heat dissipating structure 7d may be disposed around and connected to the first heat dissipating structure 5b and the second heat dissipating structure 6b. The third heat dissipating structure 7d may be configured to support the heat sink 46. The third heat dissipating structure 7d and the heat sink 46 may collectively define an accommodation space 75 for accommodating the thermal material 48 (e.g., thermal interface material (TIM)). For example, the third heat dissipating structure 7d may be disposed on and may connect to a periphery portion of the first portion 61 of the second heat dissipating structure 6b and a periphery portion of the lower portion 511 of the first portion 51 of the first heat dissipating structure 5b. A thickness of the third heat dissipating structure 7d may be greater than the thickness of the upper portion 512 of the first portion 51 of the first heat dissipating structure 5b. Thus, a level of a top end of the third heat dissipating structure 7d may be higher than a top end of the first heat dissipating structure 5b and a top end of the second heat dissipating structure 6b. In some embodiments, the third heat dissipating structure 7 may include a first portion 71 disposed on the first portion 61 of the second heat dissipating structure 6b and a second portion 72 disposed on the first portion 71. A width of the first portion 71 may be less than a width of the second portion 72. The heat sink 46 may contact the third heat dissipating structure 7d. In addition, the thermal material 48 may be outflanked or surrounded by the third heat dissipating structure 7d.

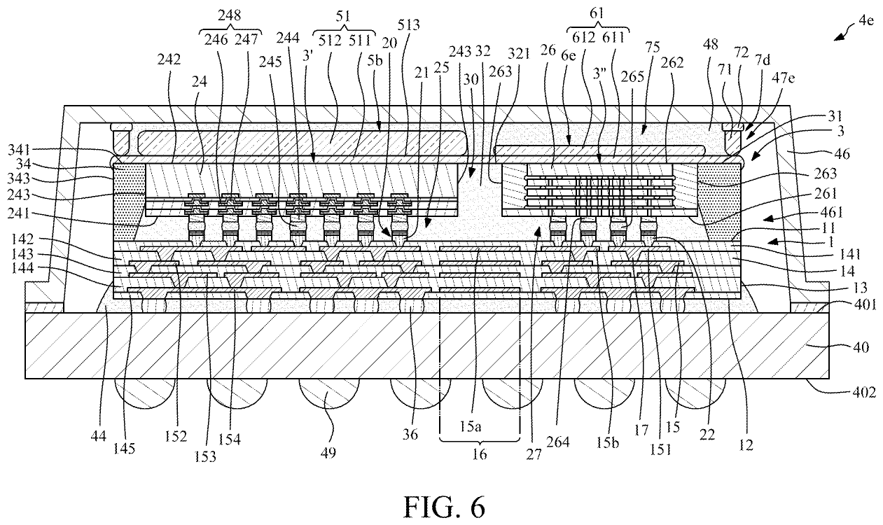

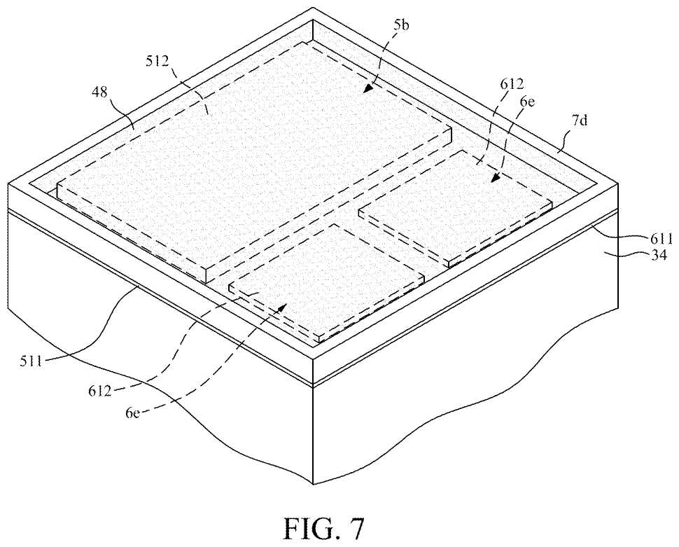

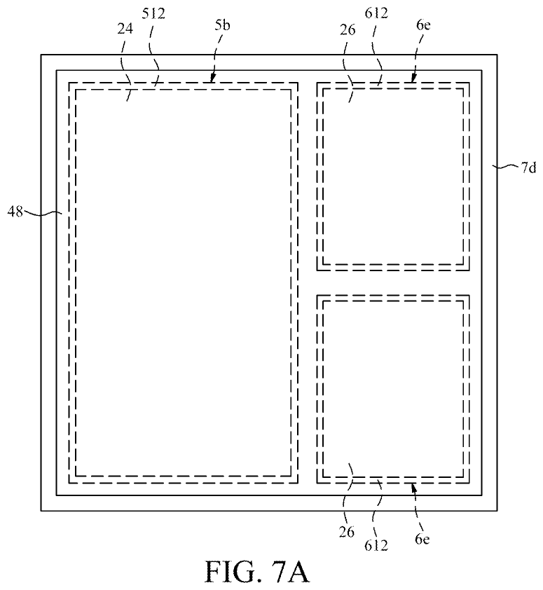

FIG. 6 illustrates a cross-sectional view of an electronic structure 4e according to some embodiments of the present disclosure. FIG. 7 illustrates a perspective view of the electronic structure 4e of FIG. 6. FIG. 7A illustrates a top view of FIG. 7. The electronic structure 4e of FIG. 6 and FIG. 7 is similar to the electronic structure 4d of FIG. 5, except that the first portion 61 of the second heat dissipating structure 6e of the thermal structure 47e may include a lower portion 611 and an upper portion 612 disposed on the lower portion 611. A thickness of the upper portion 612 may be greater than or equal to a thickness of the lower portion 611. There may be a visible interface or an obvious interface formed between the lower portion 611 and the upper portion 612. The thickness of the lower portion 511 of the first portion 51 of the first heat dissipating structure 5b is equal to a thickness of the lower portion 611 of the first portion 61 of the second heat dissipating structure 6e. The thickness of the upper portion 512 of the first portion 51 of the first heat dissipating structure 5b is greater than a thickness of the upper portion 612 of the first portion 61 of the second heat dissipating structure 6e. As shown in FIG. 7, the thermal material 48 may be outflanked or surrounded by the third heat dissipating structure 7d.

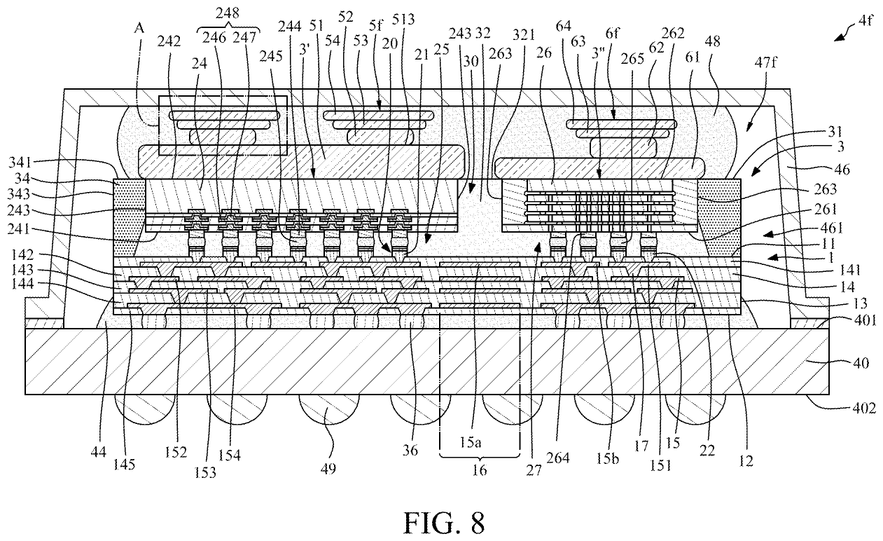

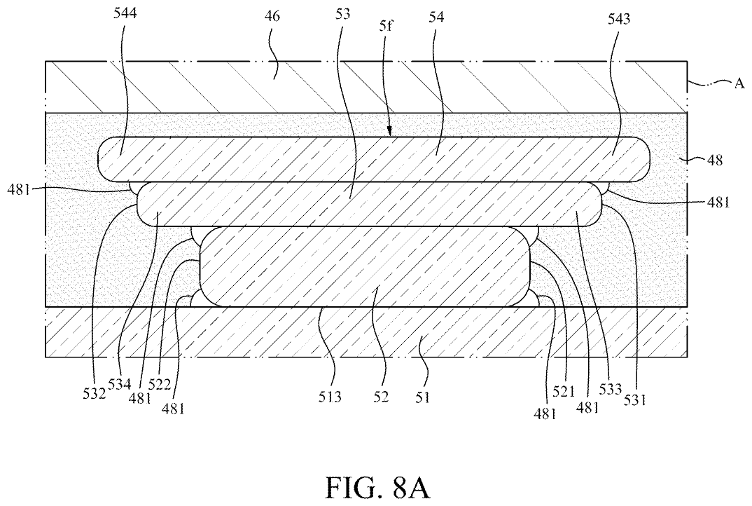

FIG. 8 illustrates a cross-sectional view of an electronic structure 4f according to some embodiments of the present disclosure. The electronic structure 4f of FIG. 8 is similar to the electronic structure 4 of FIG. 1, except for the structure of the thermal structure 47f. The thermal structure 47f may include a first heat dissipating structure 5f and a second heat dissipating structure 6f separated from the first heat dissipating structure 5f. The first heat dissipating structure 5f may include a first portion 51, a plurality of second portions 52, a plurality of third portions 53 and a plurality of fourth portions 54. The second portions 52 may be disposed on the first portion 51. Each of the third portions 53 may be disposed on each of the second portions 52. Each of the fourth portions 54 may be disposed on each of the third portions 53. A width of the first portion 51 may be greater than a width of the second portion 52. A width of the third portion 53 may be greater than a width of the second portion 52. A width of the fourth portion 54 may be greater than a width of the third portion 53. The portions 51, 52, 53, 54 of the first heat dissipating structure 5f have different widths. Thus, a thermal path may be formed by the arrangement of stacking along a certain direction.

The second heat dissipating structure 6f may include a first portion 61, a second portion 62, a third portion 63 and a fourth portion 64. The second portion 62 may be disposed on the first portion 61. The third portion 63 may be disposed on the second portion 62. The fourth portion 64 may be disposed on the third portions 63. A width of the first portion 61 may be greater than a width of the second portion 62. A width of the third portion 63 may be greater than a width of the second portion 62. A width of the fourth portion 64 may be greater than a width of the third portion 63. The portions 61, 62, 63, 64 of the second heat dissipating structure 6f have different widths. A thickness of the first portion 61 of the second heat dissipating structure of may be less than a thickness of the first portion 51 of the first heat dissipating structure 5f.

FIG. 8A illustrates an enlarged view of a region “A” in FIG. 8. In some embodiments, an end of an upper one of the portions 52, 53, 54 extends beyond a lateral surface of a lower one of the portions 52, 53, 54 under the upper one of the portions 52, 53, 54. Thus, an end of an upper one of the portions 52, 53, 54 does not vertically overlap a lower one of the portions 52, 53, 54 under the upper one of the portions 52, 53, 54. For example, the third portion 53 may be an upper portion corresponding to the second portion 52 (such as a lower portion) under the third portion 53. A first end 533 of the third portion 53 (e.g., the upper portion) may extend beyond a first lateral surface 521 of the second portion 52 (e.g., the lower portion). A second end 534 of the third portion 53 (e.g., the upper portion) may extend beyond a second lateral surface 522 of the second portion 52 (e.g., the lower portion). The first end 533 is opposite to the second end 534, and the first lateral surface 521 is opposite to the second lateral surface 522. The first end 533 and the second end 534 do not vertically overlap the second portion 52. Each of the first end 533 and the second end 534 is an overhanging portion.

Similarly, the fourth portion 54 may be an upper portion corresponding to the third portion 53 (such as a lower portion) under the fourth portion 54. A first end 543 of the fourth portion 54 (e.g., the upper portion) may extend beyond a first lateral surface 531 of the third portion 53 (e.g., the lower portion). A second end 544 of the fourth portion 54 (e.g., the upper portion) may extend beyond a second lateral surface 532 of the third portion 53 (e.g., the lower portion). The first end 543 is opposite to the second end 544, and the first lateral surface 531 is opposite to the second lateral surface 532. The first end 543 and the second end 544 do not vertically overlap the third portion 53. Each of the first end 543 and the second end 544 is an overhanging portion. In addition, the thermal material 48 may define a plurality of first voids 481 located at a corner formed by a top surface of the first portion 51 and the lateral surfaces 521, 522 of the second portion 52, at a corner formed by a bottom surface of the third portion 53 and the lateral surfaces 521, 522 of the second portion 52, and at a corner formed by a bottom surface of the fourth portion 54 and the lateral surfaces 531, 532 of the third portion 53.

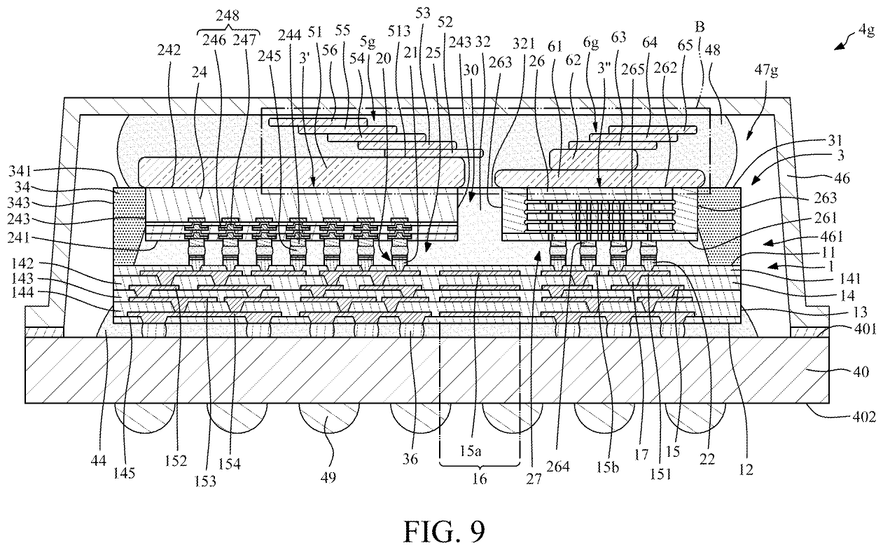

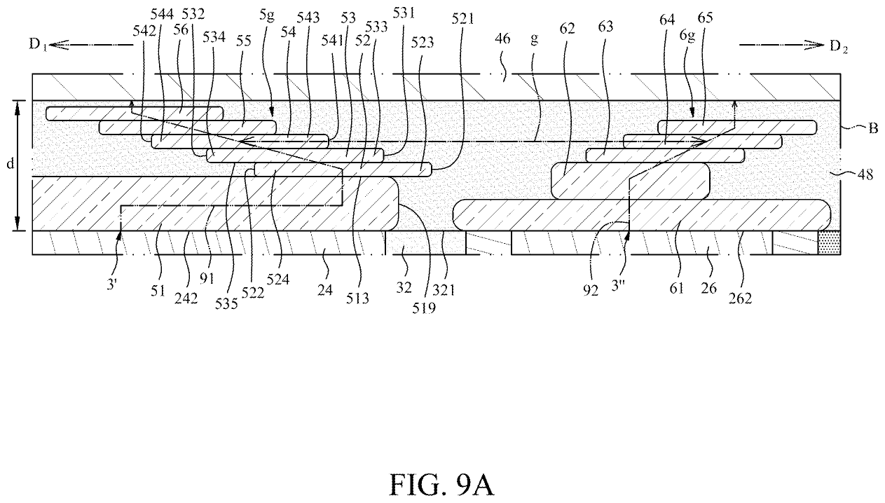

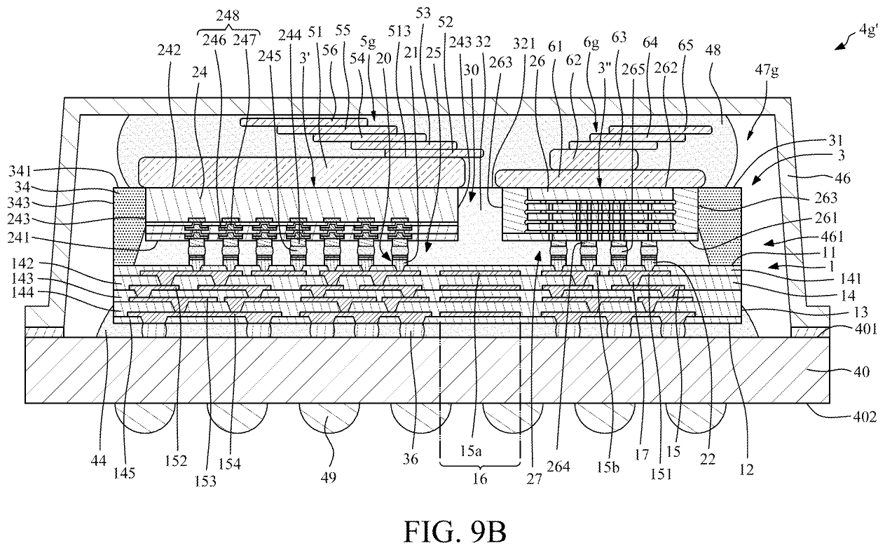

FIG. 9 illustrates a cross-sectional view of an electronic structure 4g according to some embodiments of the present disclosure. The electronic structure 4g of FIG. 9 is similar to the electronic structure 4f of FIG. 8, except for the structure of the thermal structure 47g. The thermal structure 47g may include a first heat dissipating structure 5g and a second heat dissipating structure 6g. The first heat dissipating structure 5g may include a first portion 51, a second portion 52, a third portion 53, a fourth portion 54, a fifth portion 55 and a sixth portion 56. The second portion 52 may be disposed on the first portion 51. The third portion 53 may be disposed on the second portion 52. The fourth portion 54 may be disposed on the third portion 53. A thickness and a width of the first portion 51 may be greater than a thickness and a width of the second portion 52. The second portion 52, the third portion 53, the fourth portion 54, the fifth portion 55 and the sixth portion 56 may be stacked on one another.

The second heat dissipating structure 6g may include a first portion 61, a second portion 62, a third portion 63, a fourth portion 64 and a fifth portion 65. The second portion 62 may be disposed on the first portion 61. A width of the first portion 61 may be greater than a width of the second portion 62. The second portion 62, the third portion 63, the fourth portion 64 and the fifth portion 65 may be stacked on one another.

FIG. 9A illustrates an enlarged view of a region “B” in FIG. 9. The second portion 52, the third portion 53, the fourth portion 54, the fifth portion 55 and the sixth portion 56 may have a substantially same width and thickness, and may be stacked on one another and laterally offset from one another in a first direction D1. In some embodiments, the second portion 52 may be also referred to as “a first portion”, the third portion 53 may be also referred to as “a second portion”, and the fourth portion 54 may be also referred to as “a third portion”. A first end 523 of the second portion 52 (e.g., the upper portion) may extend beyond a first lateral surface 519 of the first portion 51 (e.g., the lower portion). A second end 524 of the second portion 52 (e.g., the upper portion) may not extend beyond a lateral surface of the first portion 51 (e.g., the lower portion). A first end 533 (or a second end) of the third portion 53 (e.g., the upper portion) may not extend beyond a first lateral surface 521 (or a second lateral surface) of the second portion 52 (e.g., the lower portion). The first end 533 (or a second end) of the third portion 53 may be recessed from the first lateral surface 521 (or a second lateral surface) of the second portion 52. A second end 534 (or a first end) of the third portion 53 (e.g., the upper portion) may extend beyond a second lateral surface 522 (or a first lateral surface) of the second portion 52 (e.g., the lower portion). A first end 543 (or a second end) of the fourth portion 54 may not extend beyond a first lateral surface 531 (or a second lateral surface) of the third portion 53. The first end 543 (or a second end) of the fourth portion 54 may be recessed from the first lateral surface 531 (or a second lateral surface) of the third portion 53. A second end 544 (or a first end) of the fourth portion 54 may extend beyond a second lateral surface 532 (or a first lateral surface) of the third portion 53. The fourth portion 54 may have a first lateral surface 541 corresponding to the first end 543, and a second lateral surface 542 corresponding to the second end 544. In addition, the thermal material 48 (e.g., thermal interface material (TIM)) may extend to under the third portion 53. The thermal material 48 (e.g., thermal interface material (TIM)) may contact a bottom surface 535 of the third portion 53.

A length of the first thermal path 91 between or from the first region 3′ (e.g., the first electronic device 24) to the heat sink 46 by the first heat dissipating structure 5g is not a shortest distance d (or vertical distance or vertical gap) between the first region 3′ (e.g., the first electronic device 24) and the heat sink 46. The entire first thermal path 91 may be not a straight line. The entire first thermal path 91 may have at least one turning point. In some embodiments, the first heat dissipating structure 5 may be disposed over the first electronic device 24, and may have the first thermal path 91 extending from the first electronic device 24 toward heat sink 46. The extending direction of the first thermal path 91 may be away from a vertical projection of the second electronic device 26, so as to prevent the heat generated by the first electronic device 24 from influencing the heat dissipation efficiency over the second electronic device 26.

Similarly, the second portion 62, the third portion 63, the fourth portion 64 and the fifth portion 65 may have a substantially same width, and may be stacked on one another and laterally offset from one another in a second direction D2. The second direction D2 is opposite to the first direction D1. Thus, a length of the second thermal path 92 between or from the second region 3″ (e.g., the second electronic device 26) to the heat sink 46 by the second heat dissipating structure 6g is not a shortest distance d (or vertical distance or vertical gap) between the second region 3″ (e.g., the second electronic device 26) and the heat sink 46. The entire second thermal path 92 may be not a straight line. The entire second thermal path 92 may have at least one turning point. In some embodiments, the second heat dissipating structure 6 may be disposed over the second electronic device 26, and may have the second thermal path 92 extending from the second electronic device 26 toward heat sink 46. The first thermal path 91 is thermally insulated from the second thermal path 92, and the first thermal path 91 is non-parallel with the second thermal path 92. The extending direction of the second thermal path 92 may be away from a vertical projection of the first electronic device 24, so as to prevent the heat generated by the second electronic device 26 from influencing the heat dissipation efficiency over the first electronic device 24. A gap g between the first thermal path 91 and the second thermal path 92 increases toward the heat sink 46.

FIG. 9B illustrates a cross-sectional view of an electronic structure 4g′ according to some embodiments of the present disclosure. The electronic structure 4g′ of FIG. 9B is similar to the electronic structure 4g of FIG. 9, except that the first portion 51, the second portion 52, the third portion 53, the fourth portion 54, the fifth portion 55 and the sixth portion 56 of the first heat dissipating structure 5g may have different width, and the first portion 61, the second portion 62, the third portion 63, the fourth portion 64 and the fifth portion 65 may have different width. A width of the sixth portion 56 may be greater than a width of the fifth portion 55. The width of the fifth portion 55 may be greater than a width of the fourth portion 54. The width of the fourth portion 54 may be greater than a width of the third portion 53. The width of the third portion 53 may be greater than a width of the second portion 52, a width of the fifth portion 65 may be greater than a width of the fourth portion 64. The width of the fourth portion 64 may be greater than a width of the third portion 63.

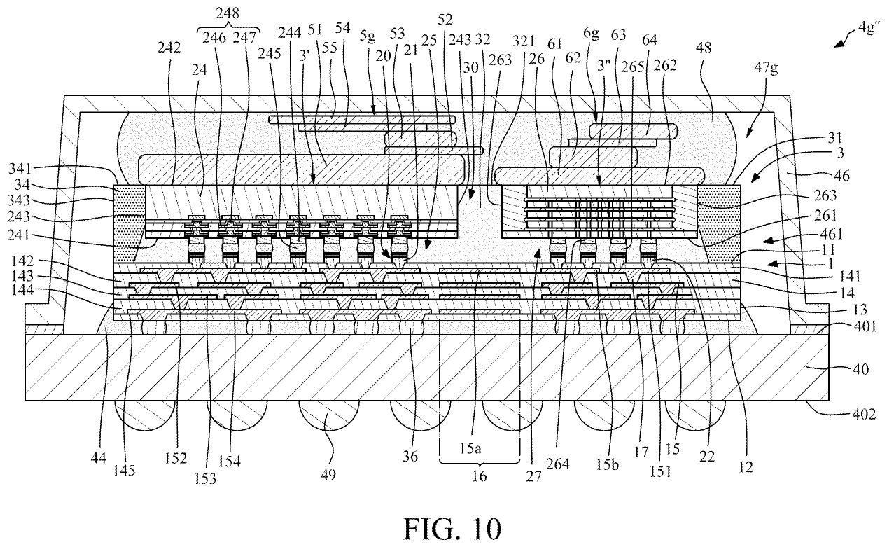

FIG. 10 illustrates a cross-sectional view of an electronic structure 4g″ according to some embodiments of the present disclosure. The electronic structure 4g″ of FIG. 10 is similar to the electronic structure 4g of FIG. 9, except that the first portion 51, the second portion 52, the third portion 53, the fourth portion 54 and the fifth portion 55 of the first heat dissipating structure 5g may have different thickness and width, and the first portion 61, the second portion 62, the third portion 63 and the fourth portion 64 may have different thickness and width.

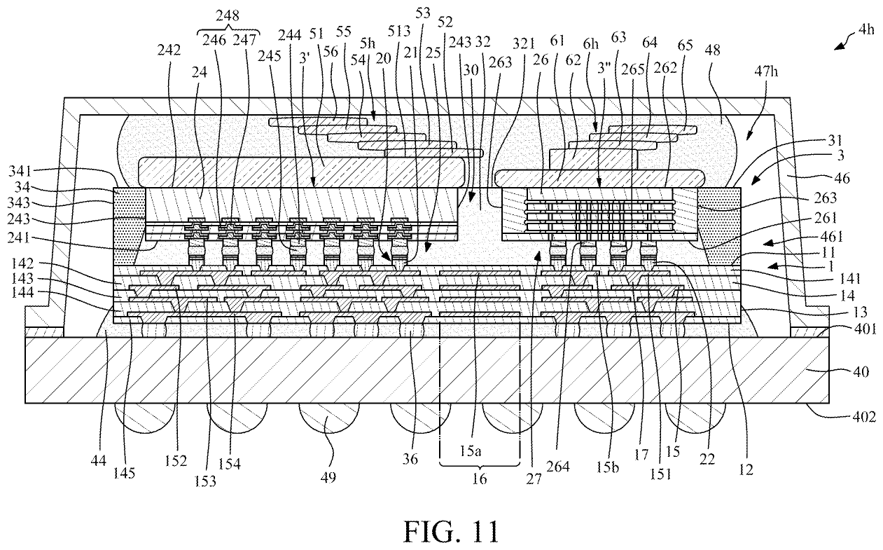

FIG. 11 illustrates a cross-sectional view of an electronic structure 4h according to some embodiments of the present disclosure. The electronic structure 4h of FIG. 11 is similar to the electronic structure 4g of FIG. 9, except for the structure of the thermal structure 47h. Each of the second portion 52, the third portion 53, the fourth portion 54, the fifth portion 55 and the sixth portion 56 of the first heat dissipating structure 5h may have a curved top surface and a curved bottom surface. Each of the second portion 62, the third portion 63, the fourth portion 64 and the fifth portion 65 of the second heat dissipating structure 6h may have a curved top surface and a curved bottom surface.

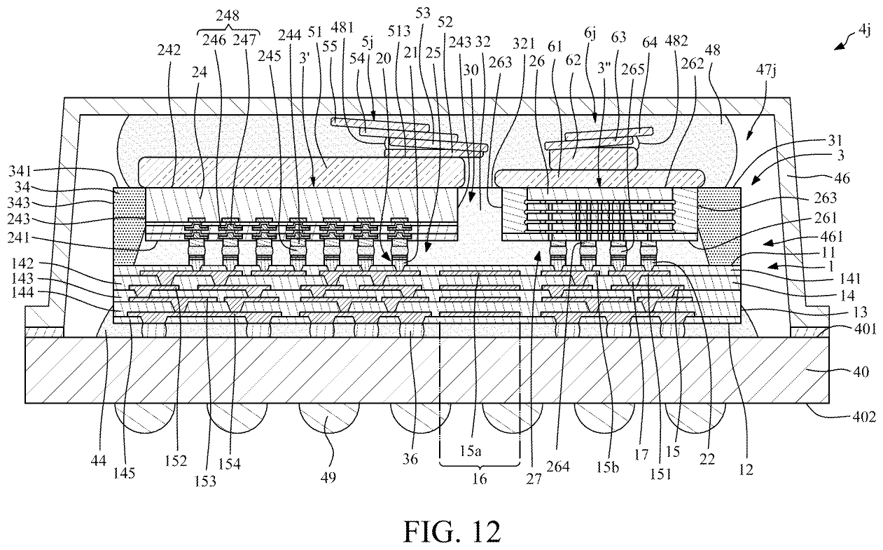

FIG. 12 illustrates a cross-sectional view of an electronic structure 4j according to some embodiments of the present disclosure. The electronic structure 4j of FIG. 12 is similar to the electronic structure 4g of FIG. 9, except for the structure of the thermal structure 47j. The third portion 53, the fourth portion 54 and the fifth portion 55 of the first heat dissipating structure 5j may be non-parallel with the first portion 51 and the second portion 52. That is, the extending direction of the third portion 53, the fourth portion 54 and the fifth portion 55 of the first heat dissipating structure 5j may be non-parallel with the extending direction of the first portion 51 and the second portion 52. The third portion 53, the fourth portion 54 and the fifth portion 55 may be tilted. For example, the second portion 52 (or the first portion) and the third portion 53 (or the second portion) may be non-parallel with each other along a horizontal direction. A portion of the second portion 52 (or the first portion) may laterally overlap with a portion of the third portion 53 (or the second portion). In addition, the thermal material 48 may define a first void 481 located between the second portion 52 and the third portion 53, and between the second portion 52 and the fourth portion 54.

The third portion 63 and the fourth portion 64 of the second heat dissipating structure 6j may be non-parallel with the first portion 61 and the second portion 62. That is, the extending direction of the third portion 63 and the fourth portion 64 of the second heat dissipating structure 6j may be non-parallel with the extending direction of the first portion 61 and the second portion 62. The third portion 63 and the fourth portion 64 may be tilted. In addition, the thermal material 48 may define a second void 482 located between the second portion 62 and the third portion 63, and between the second portion 62 and the fourth portion 64.

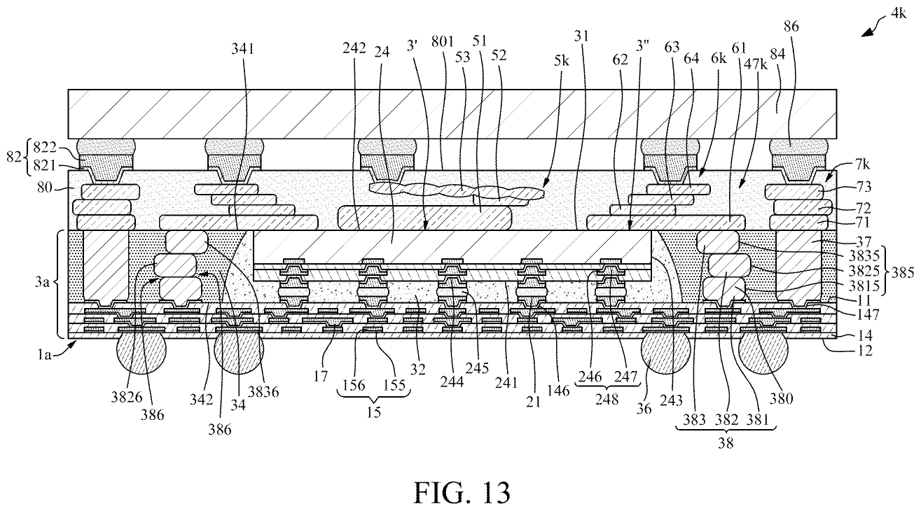

FIG. 13 illustrates a cross-sectional view of an electronic structure 4k according to some embodiments of the present disclosure. The electronic structure 4k may be also referred to as “an assembly structure” or “a semiconductor package”. The electronic structure 4k may include a package structure 3a, a thermal structure 47k (including a first heat dissipating structure 5k and a second heat dissipating structure 6k), an electrical structure 7k, a dielectric layer 80, a plurality of via strictures 82 and an upper electronic device 84.

The package structure 3a may include a wiring structure 1a, an electronic device 24, a first protection material 32, at least one vertical conductive structure 38, at least one pillar 37, an encapsulant 34 and a plurality of solder materials 36. The wiring structure 1a may be similar to the wiring structure 1 of FIG. 1. The wiring structure 1a may have a first surface 11 and a second surface 12 opposite to the first surface 11. The wiring structure 1a may include a plurality of dielectric layers 14, a plurality of circuit layers 15 in contact with the dielectric layer 14, and a plurality of protrusion pads 21. The circuit layer 15 may include a seed layer 155 and a conductive material 156 disposed on the seed layer 155. The topmost dielectric layer 14 may define a plurality of openings (including, for example, openings 146 and openings 147) to expose portions of the topmost circuit layer 15. The protrusion pads 21 may be disposed in the openings 146 and on the exposed portions of the topmost circuit layer 15.

The electronic device 24 may be the same as or similar to the first electronic device 24 of FIG. 1. The electronic device 24 may be a semiconductor device such as an application specific integrated circuit (ASIC) die. The first electronic device 24 may have a first surface 241, a second surface 242 opposite to the first surface 241, and a lateral side surface 243 extending between the first surface 241 and the second surface 242. Further, the first electronic device 24 may include a plurality of circuit layers 248 and a plurality of electrical contacts 244 disposed adjacent to the first surface 241. The circuit layer 248 may be embedded in the electronic device 24, and may include a seed layer 246 and a conductive material 247 disposed on the seed layer 246. The seed layer 246 may be formed by physical vapor deposition (PVD). The electrical contacts 244 may be electrically connected to the circuit layers 248, and may be exposed or may protrude from the first surface 241 for electrical connection. In some embodiments, the electrical contacts 244 of the electronic device 24 may be electrically connected and physically connected to the protrusion pads 21 through a plurality of solder materials 245. In other words, the electronic device 24 may be electrically connected to the wiring structure 1a by flip-chip bonding. The electronic device 24 may include a first region 3′ and a second region 3″ different from the first region 3′. A first predetermined temperature at the first region 3′ is higher than a second predetermined temperature at the second region 3″ during the operation of the package structure 3a.

The vertical conductive structure 38 may be disposed around the electronic device 24, and may be formed through a first chemical deposition process such as a 3D printing technique or 3D printing technology. A portion of the vertical conductive structure 38 may be disposed in the opening 147. The vertical conductive structure 38 may include a plurality of portions 380 built on one another or stacked on one another. In some embodiments, the portions 380 may be laterally offset from one another. That is, the vertical central axes of the portions 380 may be misaligned with each other. Adjacent two of the plurality of portions 380 may form a step structure. Each of the portions 380 may include a rounded corner. The vertical conductive structure 38 may be encapsulated in the encapsulant 34. The vertical conductive structure 38 may have a discontinuous lateral surface 385 or a non-flat lateral surface. A recess 386 may be formed between adjacent two of the portions 380, and the encapsulant 34 may extend into the recess 386. The vertical conductive structure 38 may be configured to dissipate a heat generated by the electronic device 24. That is, the vertical conductive structure 38 may be a portion of a thermal path. In some embodiments, the vertical conductive structure 38 may be configured to transmit signal or power. That is, the vertical conductive structure 38 may be a portion of a signal transmission path or a portion of a power transmission path.

In some embodiments, an end of an upper one of the portions 380 extends beyond a lateral surface of a lower one of the portions 380 under the upper one of the portions 380. Thus, an end of an upper one of the portions 380 does not vertically overlap a lower one of the portions 380 under the upper one of the portions 380. For example, the portions 380 of the vertical conductive structure 38 may include a first portion 381, a second portion 382 disposed on the first portion 381, and a third portion 383 disposed on the second portion 382. The first portion 381 may have a lateral surface 3815. The second portion 382 may have a lateral surface 3825. The third portion 383 may have a lateral surface 3835. The lateral surface 385 of the vertical conductive structure 38 may include the lateral surface 3815 of the first portion 381, the lateral surface 3825 of the second portion 382, and the lateral surface 3835 of the third portion 383.

The third portion 383 may be an upper portion corresponding to the second portion 382 (e.g., the lower portion) under the third portion 383. An end 3836 of the third portion 383 (e.g., the upper portion) may extend beyond the lateral surface 3825 of the second portion 382 (e.g., the lower portion). The second portion 382 may be an upper portion corresponding to the first portion 381 (e.g., the lower portion) under the second portion 382. An end 3826 of the second portion 382 (e.g., the upper portion) may extend beyond the lateral surface 3815 of the first portion 381 (e.g., the lower portion). The recess 386 may be formed between the first portion 381 and the second portion 382, and the encapsulant 34 may extend into the recess 386.

The pillar 37 may be disposed around the electronic device 24 and the vertical conductive structure 38, and may be formed by physical vapor deposition (PVD). A portion of the pillar 37 may be disposed in the opening 147. The pillar 37 may be a monolithic structure, and may have a single continuous lateral surface. The pillar 37 may be encapsulated in the encapsulant 34. The vertical conductive structure 38 may be closer to the electronic device 24 than the pillar 37 is. The pillar 37 may be configured to transmit signal or power. That is, the pillar 37 may be a portion of a signal transmission path or a portion of a power transmission path.

The encapsulant 34 may encapsulate the electronic device 24, the vertical conductive structure 38, the pillar 37 and the wiring structure 1a. One end of the vertical conductive structure 38 may be exposed by a top surface of the encapsulant 34 (e.g., the top surface 31 of the package structure 3a). One end of the pillar 37 may be exposed by a top surface of the encapsulant 34 (e.g., the top surface 31 of the package structure 3a). Thus, both the vertical conductive structure 38 and the pillar 37 may extend through the encapsulant 34.

The thermal structure 47k may include a first heat dissipating structure 5k and a second heat dissipating structure 6k, and may be disposed on or disposed over the top surface 31 of the package structure 3a (e.g., the first surface 341 of the encapsulant 34 and the second surface 242 of the first electronic device 24). The first heat dissipating structure 5k and the second heat dissipating structure 6k may be configured to dissipate the heat generated by the electronic device 24, and may be formed through a second chemical deposition process such as a 3D printing technique or 3D printing technology.

The first heat dissipating structure 5k may be disposed over or disposed on the first region 3′ of the electronic device 24. The first heat dissipating structure 5k may include a first portion 51, a second portion 52 and a third portion 53 stacked on one another. The first portion 51 may contact the first region 3′. An end of the second portion 52 may extend beyond a lateral surface of the first portion 51. An end of the third portion 53 may extend beyond a lateral surface of the second portion 52. The extending direction of the third portion 53 may be non-parallel with the extending direction of the first portion 51 and the second portion 52. The third portion 53 may be tilted. The third portion 53 may have an inconsistent thickness. The third portion 53 may have a wavy top surface and a wavy bottom surface.

The second heat dissipating structure 6k may be disposed over or disposed on the second region 3″ of the electronic device 24. The second heat dissipating structure 6k may include a first portion 61, a second portion 62, a third portion 63 and a fourth portion 64. The first portion 61 may contact the second region 3″ and the third portion 383 of the vertical conductive structure 38. Thus, the second heat dissipating structure 6k may be electrically connected to and/or thermally connected to the vertical conductive structure 38. A thickness of the first portion 61 may be less than a thickness of the first portion 51. The second portion 62, the third portion 63 and the fourth portion 64 may have a substantially same width and thickness, and may be stacked on one another and laterally offset from one another in a direction.

The electrical structure 7k may be disposed over or disposed on the pillar 37. The electrical structure 7k may be configured to transmit signal or power, and may be formed through the second chemical deposition process such as a 3D printing technology. That is, the electrical structure 7k, the first heat dissipating structure 5k and the second heat dissipating structure 6k may be formed through a same chemical deposition process such as a 3D printing technology. The electrical structure 7k may include a first portion 71, a second portion 72 and a third portion 73. The first portion 71 may contact the pillar 37. Thus, the electrical structure 7k may be electrically connected to the pillar 37. The second portion 72 and the third portion 73 may have a substantially same width and thickness, and may be stacked on one another and laterally offset from one another.

The dielectric layer 80 may cover the thermal structure 47k (including the first heat dissipating structure 5k and the second heat dissipating structure 6k), the electrical structure 7k and the package structure 3a. The dielectric layer 80 may include a molding compound with or without filler. Alternatively, the dielectric layer 80 may be made of a cured photoimageable dielectric (PID) material such as epoxy or polyimide (PI) including photoinitiators. The dielectric layer 80 may include a top surface 801. The dielectric layer 80 may define a plurality of openings recessed from the top surface 801 so as to expose a portion of the first heat dissipating structure 5k, a portion of the second heat dissipating structure 6k and a portion of the electrical structure 7k.

The via strictures 82 may be disposed in the openings of the dielectric layer 80 to contact the first heat dissipating structure 5k, the second heat dissipating structure 6k and the electrical structure 7k. Thus, the via strictures 82 may be embedded in the dielectric layer 80 and electrically connected or thermally connected to the first heat dissipating structure 5k, the second heat dissipating structure 6k and the electrical structure 7k. The via stricture 82 may include a seed layer 821 and a conductive material 822 disposed on the seed layer 821. The seed layer 821 may be formed by physical vapor deposition (PVD). The conductive material 822 may be formed by electroplating. The first heat dissipating structure 5k, the second heat dissipating structure 6k and the electrical structure 7k do not include seed layer. A grain size and a lattice of the material of the first heat dissipating structure 5k, the second heat dissipating structure 6k and the electrical structure 7k may be different from a grain size and a lattice of the material of the seed layer 821 of the via stricture 82.

The upper electronic device 84 may be attached to the via strictures 82 through a plurality of reflowable materials 86 (such as solder materials). Thus, the upper electronic device 84 may be electrically connected or thermally connected to the first heat dissipating structure 5k, the second heat dissipating structure 6k and the electrical structure 7k through the reflowable materials 86 and the via strictures 82. In some embodiments, the upper electronic device 84 may include a semiconductor chip, a package structure, a patterned circuit layer, a substrate or an interposer.

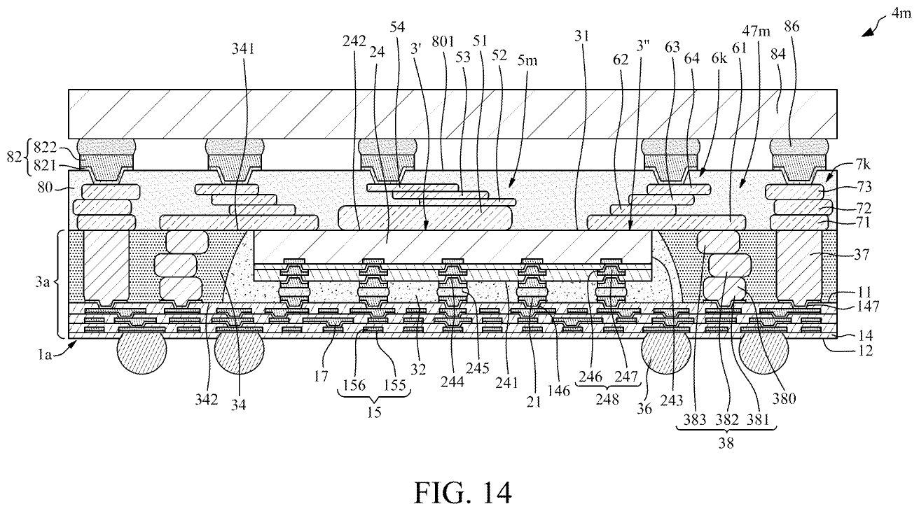

FIG. 14 illustrates a cross-sectional view of an electronic structure 4m according to some embodiments of the present disclosure. The electronic structure 4m of FIG. 14 is similar to the electronic structure 4k of FIG. 13, except for the structure of the first heat dissipating structure 5m of the thermal structure 47m. The first heat dissipating structure 5m may include a first portion 51, a second portion 52, a third portion 53 and a fourth portion 54 that may be the same as or similar to the first portion 51, the second portion 52, the third portion 53 and the fourth portion 54 of the first heat dissipating structure 5g of FIG. 9.

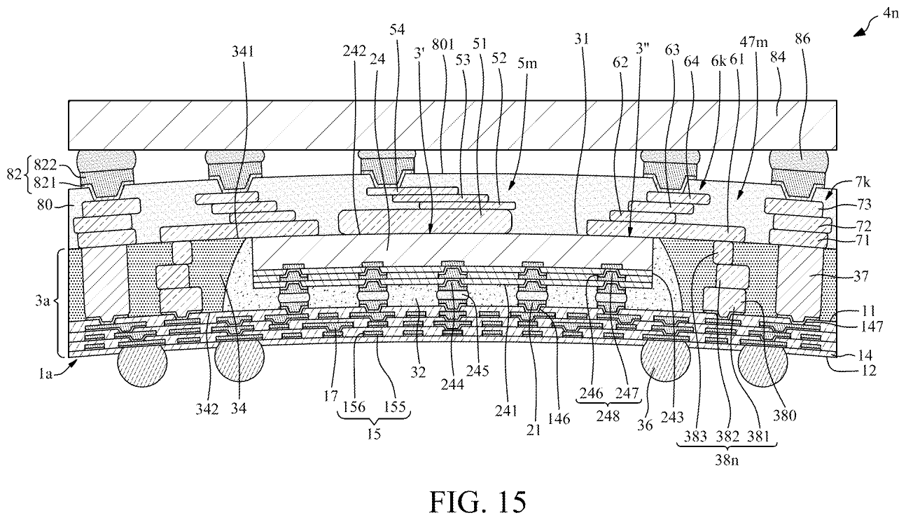

FIG. 15 illustrates a cross-sectional view of an electronic structure 4n according to some embodiments of the present disclosure. The electronic structure 4n of FIG. 15 is similar to the electronic structure 4m of FIG. 14, and the differences therebetween are described as follows. The package structure 3a and the dielectric layer 80 may have a convex warpage (or crying warpage). The package structure 3a and the dielectric layer 80 may be convex toward the upper electronic device 84. Thus, the gap between the upper electronic device 84 and the top surface 801 of the dielectric layer 80 may gradually increase from a center portion of the top surface 801 of the dielectric layer 80 toward a periphery portion of the top surface 801 of the dielectric layer 80.

In addition, in the vertical conductive structure 38n, a width of an upper one of the portions 380 is less than a width of a lower one of the portions 380 under the upper one of the portions 380. For example, the third portion 383 may be an upper portion corresponding to the second portion 382 (such as a lower portion) under the third portion 383. A width of the third portion 383 (e.g., the upper portion) may be less than a width of the second portion 382 (e.g., the lower portion). The second portion 382 may be an upper portion corresponding to the first portion 381 (such as a lower portion) under the second portion 382. A width of the second portion 382 (e.g., the upper portion) may be less than a width of the first portion 381 (e.g., the lower portion). The shape of the vertical conductive structure 38n may reduce the warpage of the package structure 3a.

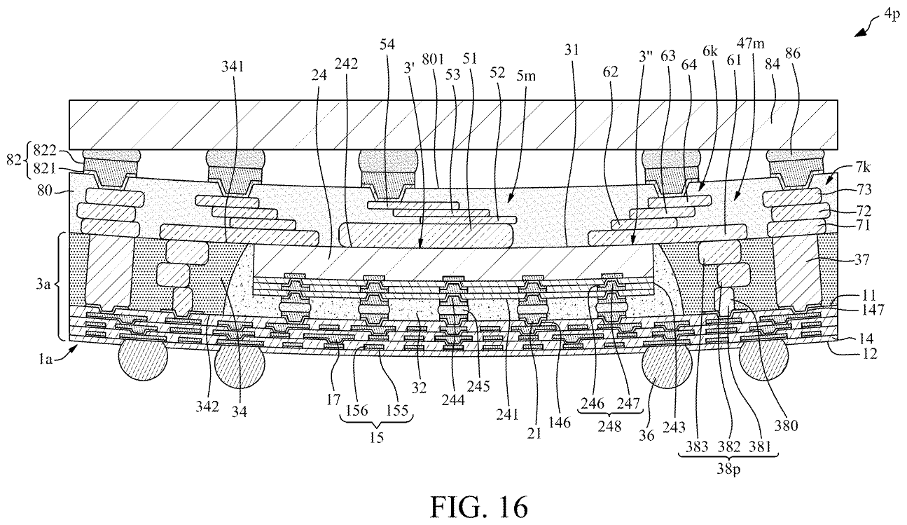

FIG. 16 illustrates a cross-sectional view of an electronic structure 4p according to some embodiments of the present disclosure. The electronic structure 4p of FIG. 16 is similar to the electronic structure 4m of FIG. 14, and the differences therebetween are described as follows. The package structure 3a and the dielectric layer 80 may have a concave warpage (or smiling warpage). The package structure 3a and the dielectric layer 80 may be concave toward the upper electronic device 84. Thus, the gap between the upper electronic device 84 and the top surface 801 of the dielectric layer 80 may gradually decrease from a center portion of the top surface 801 of the dielectric layer 80 toward a periphery portion of the top surface 801 of the dielectric layer 80.

In addition, in the vertical conductive structure 38p, a width of an upper one of the portions 380 is greater than a width of a lower one of the portions 380 under the upper one of the portions 380. For example, the third portion 383 may be an upper portion corresponding to the second portion 382 (such as a lower portion) under the third portion 383. A width of the third portion 383 (e.g., the upper portion) may be greater than a width of the second portion 382 (e.g., the lower portion). The second portion 382 may be an upper portion corresponding to the first portion 381 (such as a lower portion) under the second portion 382. A width of the second portion 382 (e.g., the upper portion) may be greater than a width of the first portion 381 (e.g., the lower portion). The shape of the vertical conductive structure 38p may reduce the warpage of the package structure 3a.

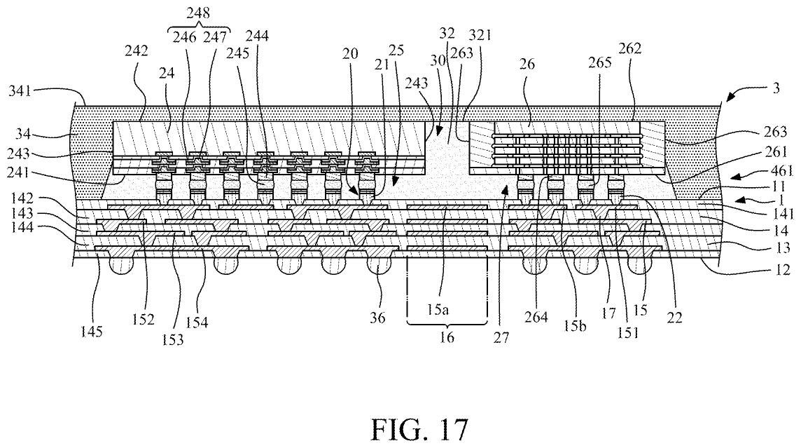

FIG. 17 through FIG. 22 illustrate a method for manufacturing an electronic structure according to some embodiments of the present disclosure. In some embodiments, the method is for manufacturing the electronic structure 4 of FIG. 1.

Referring to FIG. 17, a package structure 3 is provided. The package structure 3 may be the same as or similar to the package structure 3 of FIG. 1 except that the encapsulant 34 may cover the second surface 242 of the first electronic device 24, the second surface 262 of the second electronic device 26 and the top surface 321 of the first protection material 32 in the gap 30.

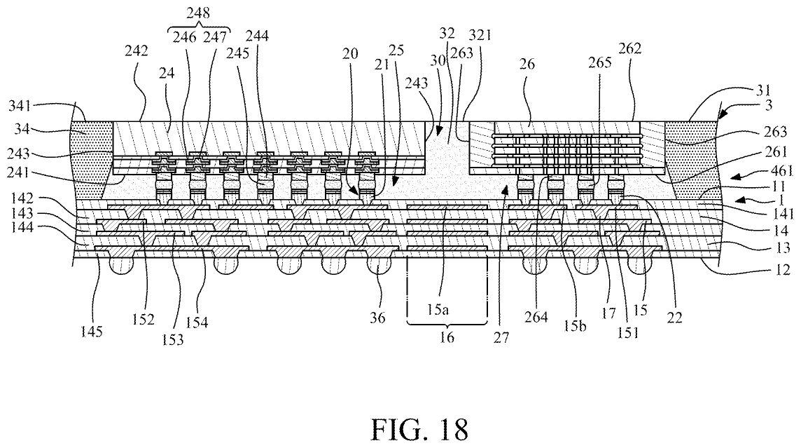

Referring to FIG. 18, a grinding process is conducted so that the first surface 341 of the encapsulant 34, the second surface 242 of the first electronic device 24, the second surface 262 of the second electronic device 26 and the top surface 321 of the first protection material 32 in the gap 30 may be substantially coplanar with each other so as to form a top surface 31 of the package structure 3.

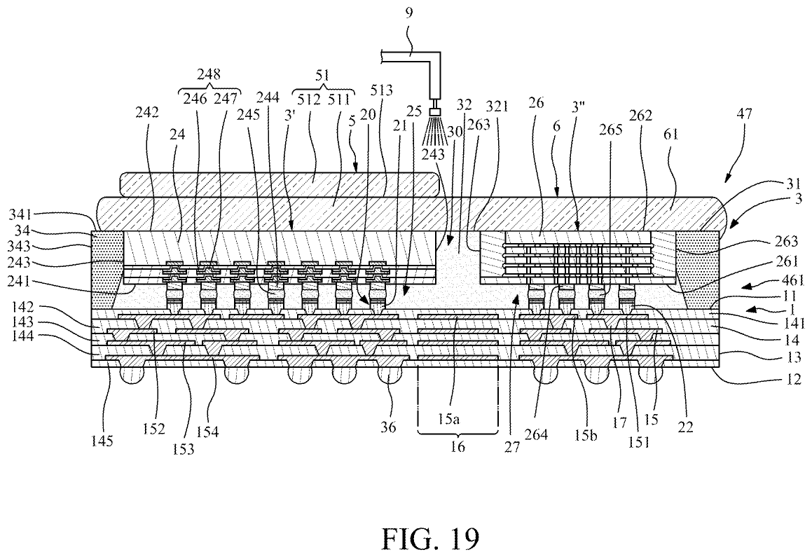

Referring to FIG. 19, a singulation process may be conducted to form the package structure 3. Then, a thermal structure 47 (including a first heat dissipating structure 5 and a second heat dissipating structure 6) is formed or disposed on the top surface 31 of the package structure 3 (e.g., the first surface 341 of the encapsulant 34, the second surface 242 of the first electronic device 24, the second surface 262 of the second electronic device 26 and the top surface 321 of the first protection material 32). In some embodiments, the singulation process may be conducted after the thermal structure 47 is formed.

The thermal structure 47 (including a first heat dissipating structure 5 and a second heat dissipating structure 6) of FIG. 19 may be the same as or similar to the thermal structure 47 (including a first heat dissipating structure 5 and a second heat dissipating structure 6) of FIG. 1. The first heat dissipating structure 5 and the second heat dissipating structure 6 may be formed through a chemical deposition process such as a 3D printing technology through a 3D printing apparatus 9. The first heat dissipating structure 5 may be formed or disposed over or disposed on the first region 3′ (e.g., the first electronic device 24). The second heat dissipating structure 6 may be formed or disposed over or disposed on the second region 3″ (e.g., the second electronic device 26).

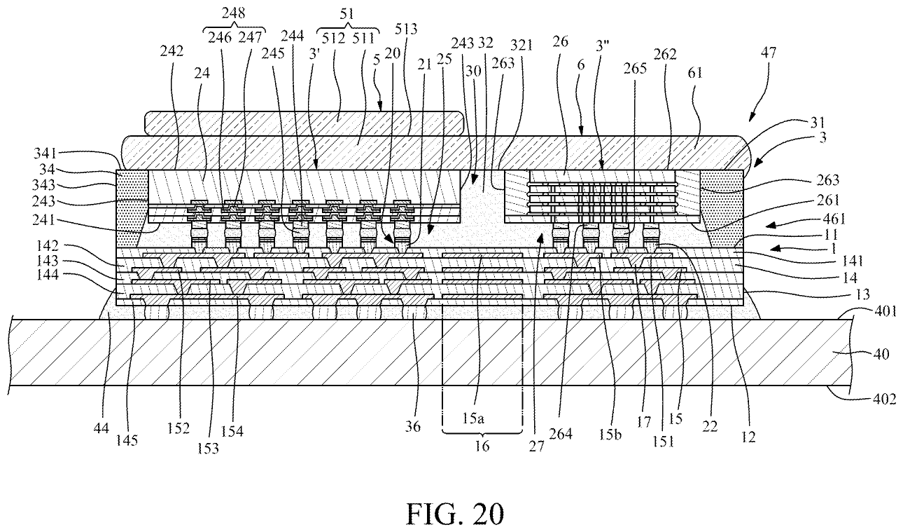

Referring to FIG. 20, the package structure 3 is electrically connected to a first surface 401 of a base substrate 40 through the solder materials 36. Then, a second protection material 44 (i.e., an underfill) is formed or disposed in a space between the package structure 3 and the base substrate 40 so as to cover and protect the solder materials 36.

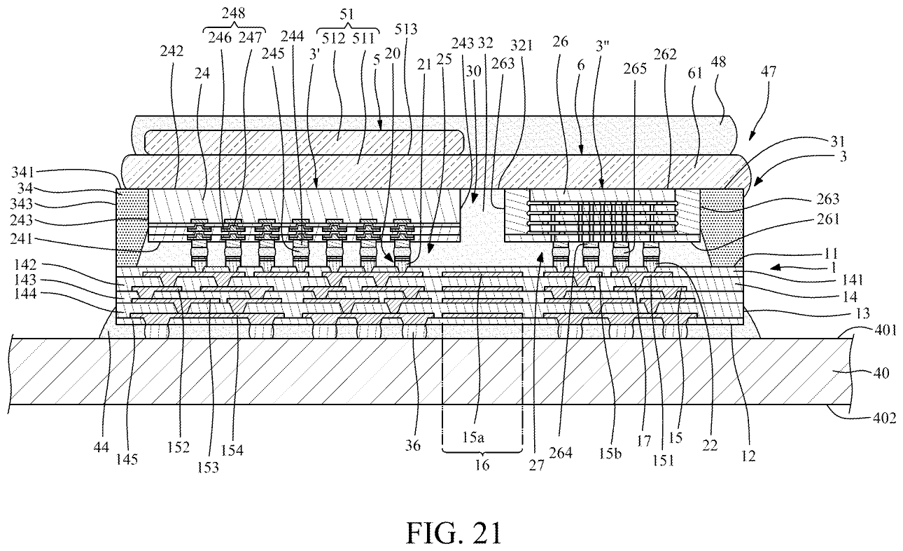

Referring to FIG. 21, a thermal material 48 (e.g., a thermal interface material (TIM)) is formed or disposed to cover the first heat dissipating structure 5 and the second heat dissipating structure 6.

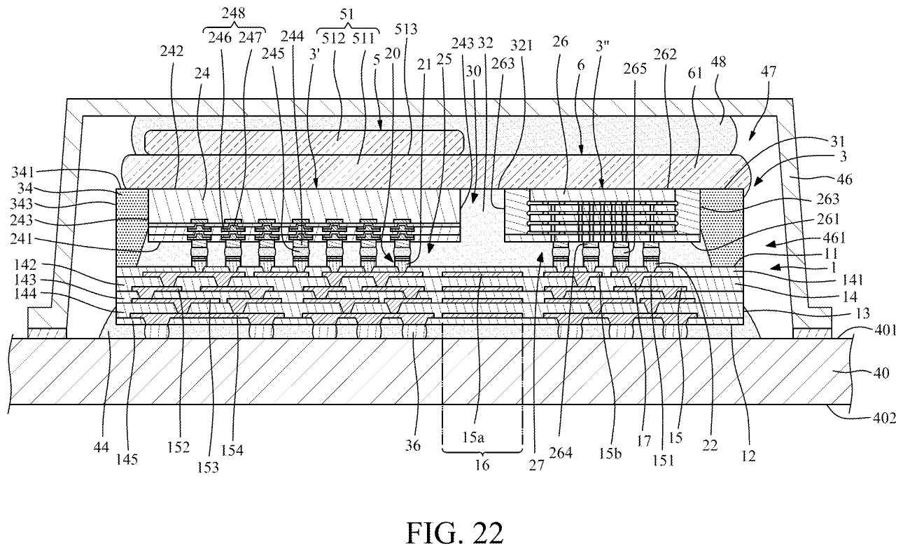

Referring to FIG. 22, the heat sink 46 is provided. The heat sink 46 may be a cap or hat structure, and may define a cavity 461 for accommodating the package structure 3. A portion of the heat sink 46 may be attached to the top surface 31 of the package structure 3 through the thermal material 48 (e.g., thermal interface material (TIM)). The heat sink 46 may be thermally connected with the first heat dissipating structure 5 and the second heat dissipating structure 6 through the thermal material 48. Another portion (e.g., bottom portion) of the heat sink 46 may be attached to or thermally connected to the base substrate 40 through an adhesive material.

Then, the external connectors 49 (e.g., solder balls) are formed or disposed on the second surface 402 of the base substrate 40 for external connection. Then, a singulation process may be conducted to the base substrate 40 so as to obtain a plurality of electronic structures 4 shown in FIG. 1.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic structure, comprising:
a package structure having a top surface including a first region and a second region, wherein a first predetermined temperature at the first region is higher than a second predetermined temperature at the second region;
a first heat dissipating structure including a first portion disposed on the first region; and
a second heat dissipating structure including a first portion disposed on the second region, wherein the first portion of the first heat dissipating structure and the first portion of the second heat dissipating structure are concurrently formed through a 3D printing technique, and wherein a thickness of the first portion of the first heat dissipating structure is greater than a thickness of the first portion of the second heat dissipating structure.

2. The electronic structure of claim 1, wherein the package structure includes:
a first electronic device disposed corresponding to the first region, and is configured to generate the first predetermined temperature;
a second electronic device disposed corresponding to the second region, and is configured to generate the second predetermined temperature; and
an encapsulant encapsulating the first electronic device and the second electronic device.

3. The electronic structure of claim 2, wherein the first heat dissipating structure is separated from the second heat dissipating structure.

4. The electronic structure of claim 3, further comprising a thermal interface material extending between the first heat dissipating structure and the second heat dissipating structure, and connecting to a heat sink.

5. The electronic structure of claim 4, further comprising a third heat dissipating structure configured to support the heat sink, wherein the third heat dissipating structure and the heat sink collectively define an accommodation space for accommodating the thermal interface material.

6. The electronic structure of claim 5, wherein a level of a top end of the third heat dissipating structure is higher than a top end of the first heat dissipating structure and a top end of the second heat dissipating structure.

7. The electronic structure of claim 6, wherein the heat sink is spaced apart from the first heat dissipating structure and the second heat dissipating structure.

8. An electronic structure, comprising:
a package structure including a first electronic device and a second electronic device encapsulated by an encapsulant;
a heat sink disposed over the package structure;
a first heat dissipating structure disposed over the first electronic device, and having a first thermal path toward heat sink; and
a second heat dissipating structure disposed over the second electronic device, and having a second thermal path toward heat sink, wherein the first thermal path is thermally insulated from the second thermal path, and the first thermal path is non-parallel with the second thermal path.

9. The electronic structure of claim 8, wherein a gap between the first thermal path and the second thermal path increases toward the heat sink.

10. The electronic structure of claim 8, wherein the first heat dissipating structure includes a first portion and a second portion disposed on the first portion, wherein a first end of the second portion extends beyond a first lateral surface of the first portion, and a second end of the second portion is recessed from a second lateral surface of the first portion.

11. The electronic structure of claim 10, wherein the first heat dissipating structure further includes a third portion disposed on the second portion, wherein a first end of the third portion extends beyond a first lateral surface of the second portion, and a second end of the third portion is recessed from a second lateral surface of the second portion.

12. The electronic structure of claim 10, wherein the first portion and the second portion are non-parallel with each other along a horizontal direction.

13. The electronic structure of claim 12, wherein a portion of the first portion laterally overlaps with a portion of the second portion.

14. The electronic structure of claim 10, wherein the second portion has an inconsistent thickness.

15. The electronic structure of claim 10, further comprising a thermal interface material extending to under the second portion.

16. The electronic structure of claim 8, wherein a length of the first thermal path between the first electronic device and the heat sink is not a shortest distance between the first electronic device and the heat sink, and a length of the second thermal path between the second electronic device and the heat sink is not a shortest distance between the second electronic device and the heat sink.

17. An electronic structure, comprising:
a package structure including:
an electronic device;
an encapsulant encapsulating the electronic device; and
a vertical conductive structure encapsulated in the encapsulant and having a discontinuous lateral surface.

18. The electronic structure of claim 17, wherein the vertical conductive structure includes a first portion and a second portion disposed on the first portion, and an end of the second portion extends beyond a lateral surface of the first portion.

19. The electronic structure of claim 17, wherein the package structure further comprises a pillar encapsulated in the encapsulant, wherein the vertical conductive structure is closer to the electronic device than the pillar is, the vertical conductive structure is configured to dissipate a heat, and the pillar is configured to transmit signal or power.

20. The electronic structure of claim 17, wherein the vertical conductive structure includes a first portion and a second portion disposed on the first portion, wherein a recess is formed between the first portion and the second portion, and the encapsulant extends into the recess.
